(19) United States
(12) Patent Application Publication
(10) Pub. No.: US 2011/0317855 A1
(43) Pub. Date: Dec. 29, 2011

(54) IMPROVEMENTS IN OR RELATING TO USER INTERFACES AND ASSOCIATED APPARATUS AND METHODS

(75) Inventors: Mattias Andersson, Johanneshov (SE); Zachary Ng, North Point (HK); Manuel Gattinger, London (GB); Lianne Mallett, London (GB); Nicola Ralston, London (GB); Edwin Shannon, London (GB); Shunjiro Eguchi, Espoo (FI); Joeske Schellen, London (GB); Alejandro Sanguinetti, Helsinki (FI); Roni Burrell, Tel-Aviv (IL); Tom Jenkins, London (GB); Daniel Dhondt, Espoo (FI)

(73) Assignee: NOKIA CORPORATION, Espoo (FI)

(21) Appl. No.: 12/810,003

(22) PCT Filed: Dec. 21, 2007
(86) PCT No.: PCT/EP2007/011338

§ 371 Date: Feb. 23, 2011

(51) Int. Cl. H03G 3/00

(52) U.S. Cl. 381/109

(57) ABSTRACT

An apparatus for providing audio connection of a speaker arrangement, with an apparatus for providing audio to the speaker arrangement, using a connection element of the apparatus for providing audio connection, wherein the apparatus for providing audio connection comprises a connection element/connector body, and a user input interface arranged to provide for control of an audio setting of the audio, providable by the speaker arrangement, based on detected movement of the connection element/connector body.

### TECHNICAL FIELD

The present invention relates to the field of user interfaces, associated methods, computer programs and apparatus. Some specific embodiments of the present invention relate to connectors for earpieces/headsets/headphones/speakers, earpieces/headsets/headphones/speakers comprising connectors, and associated modules for the same. Such apparatus can be considered to be apparatus for providing audio connection of a speaker arrangement. In such arrangements, the speaker arrangement can, in some case, be comprised with the earpiece/headset/headphone and in other arrangements be separate to the speaker arrangement.

Such apparatus are used with electronic devices to provide audio content to one or more users. Such electronic devices can be considered as apparatus for providing audio to the speaker arrangement. In certain circumstances, these electronic devices may be, portable electronic devices, which may or may not be hand-held in use (although they may be placed in a cradle in use). Such hand-portable electronic devices include so-called Personal Digital Assistants (PDAs).

Such portable electronic devices may provide one or more audio/text/video communication functions (e.g. telecommunication, videocommunication, and/or text transmission (Short Message Service (SMS)/Multimedia Message Service (MMS)/emailing) functions), interactive/non-interactive viewing functions (e.g. web-browsing, TV/program viewing functions), music recording/playing functions (e.g. MP3 or other format and/or (FM/AM) radio broadcast recording/playing), downloading/sending of data functions, image capture function (e.g. using a (e.g. in-built) digital camera), and gaming functions.

### BACKGROUND

User interfaces exist for earpieces for electronic devices. They are often buttons, which are located with the earpieces and can be used to control an audio property/setting (e.g. volume) of audio output providable by a speaker arrangement of the earpiece.

The listing or discussion of a prior-published document or any background in this specification should not necessarily be taken as an acknowledgement that the document or background is part of the state of the art or is common general knowledge. One or more aspects/embodiments of the present invention may or may not address one or more of the background issues.

### SUMMARY

In a first aspect, there is provided an apparatus for providing audio connection of a speaker arrangement, with an apparatus for providing audio to the speaker arrangement, using a connection element of the apparatus for providing audio connection, wherein the apparatus for providing audio connection comprises a connection element/connector body, and a user input interface arranged to provide for control of an audio setting of the audio, providable by the speaker arrangement, based on detected movement of the connection element/connector body.

The apparatus for providing audio connection can comprise the connection element and/or the connector body.

In a second aspect, there is provided an apparatus for providing audio connection of a speaker arrangement, with an apparatus for providing audio to the speaker arrangement, using a connection element of the apparatus for providing audio connection, wherein the apparatus for providing audio connection comprises a user input interface arranged to provide for control of an audio setting, providable by the speaker arrangement, based on detected movement of the apparatus for providing audio connection.

When the apparatus for providing audio connection is connected, via the connection element, directly/indirectly to the apparatus for providing audio to the speaker arrangement, the user interface is usable to control an audio setting of the audio which is output/outputable to a user by the speaker arrangement. It will be appreciated that the apparatus for providing audio connection can be repeatably used by a user to provide (direct/indirect) connection to the apparatus for providing audio.

The audio setting may be controlled at the speaker arrangement, at the apparatus for providing audio connection, and/or the apparatus for providing audio. The control of an audio setting may be provided by one or more of amplifier circuitry, signal processing circuitry, such as equalisation circuitry, and/or noise reduction circuitry.

The control of an audio setting may comprise one or more of a volume of audio and quality of audio. The quality of audio may comprise one or more of a equalisation function, mono/stereo selection/output function, and noise reduction function.

The apparatus for providing audio connection may be an audio connector. The audio connector may also provide non-audio connection function (e.g. video connection function).

The apparatus for providing audio connection may comprise one or more of the speaker arrangement and the connection element.

The apparatus for providing audio connection may be one or more of a headset/earpiece/speaker (e.g. loudspeaker)/headphone.

The apparatus for providing audio connection may be arranged to provide for the control of an audio setting (only) when one or more of the connection element, apparatus for providing audio connection, and the connector is in a connected state e.g. when it is directly/indirectly connected to the apparatus for providing audio to the speaker arrangement.

The apparatus for providing audio connection may be arranged to provide for the control of an audio setting by detecting movement of one or more of the connection element, apparatus for providing audio connection, and connector with respect to an apparatus to which it is connected.

The apparatus for providing audio connection may be arranged to provide for the control of an audio setting, by detecting movement of an element of the apparatus for providing audio connection with respect to another element of the apparatus for providing audio connection. For example, relative movement of a connection head with respect to a connection element may be detected.

The apparatus for providing audio connection may be arranged to provide for the control of an audio setting by detecting absolute movement of one or more of the connection element, apparatus for providing audio connection, and the connector. For example, a gyro-MEM, or equivalent may be used.

The apparatus for providing audio connection may be arranged to provide for control of an audio setting by detecting absolute movement of one or more of the connection element, the apparatus for providing audio connection, and the connector when the connected element is in a connected state with a complementary connection element.

The apparatus for providing audio connection may be arranged to detect the movement by detecting rotational movement e.g. rotational movement of the connection element/connector. This rotational movement may be about a longitudinal axis of the connection element/connector/apparatus for providing audio connection.

The apparatus may be arranged to provide for control of an audio setting by detecting movement of the connection element with respect to movement of a complementary connection element into which it is inserted.

The apparatus may be arranged to associate anti-clockwise rotation of the connection element/connector, from the perspective of the apparatus for providing audio, with decreasing volume and clockwise rotation with increasing volume.

The apparatus for providing audio connection may be arranged to detect the movement by detecting (e.g. side-side/front-back) deflection of the apparatus for providing audio connection with respect to a non-deflected configuration of the apparatus for providing audio connection.

The apparatus for providing audio connection may comprise one or more holding areas to allow the apparatus to be held by a user (e.g. during insertion/removal of the apparatus into/out of the apparatus for providing audio). The holding area(s) may comprise the user input interface. The apparatus may be arranged to detect the movement by detecting movement of the holding area(s).

The apparatus for providing audio connection may be arranged to provide for direct/indirect physical connection of the apparatus for providing audio connection to another apparatus e.g. to provide direct/indirect connection of the apparatus for providing audio to the speaker arrangement.

The apparatus for providing audio connection may be arranged to comprise a plurality of connection elements, one to allow connection to a speaker arrangement and another to allow connection to an apparatus for providing audio.

The connection element may be one or more of a male/female connection element. The apparatus for providing audio connection may be an audio jack/plug. The audio jack may conform to one or more audio jack (¾ contacts) standards e.g. as those mentioned in WO2006/045617 (PCT/EP2005/011557).

The user input interface may be arranged to also provide user output. The user input interface may be arranged to also provide user output (e.g. comprise one or more displays/light elements) to provide a visual indication that movement has been detected.

The apparatus may be arranged to provide for control of an audio setting only when a user input interface has been used to determine that the apparatus for providing audio connection is being touched by a person/user. The same or different user input interface may be used to detect the movement and touch. The respective user input interface(s) may comprise one or more capacitive touch sensors to detect the movement/touch.

The apparatus may be arranged such that detected movement is determined using the apparatus for providing audio connection only. The apparatus may be arranged such that detected movement is determined using the apparatus for providing audio to the speaker arrangement solely, and/or in combination with the apparatus for providing audio connection. The apparatus may be arranged such that detected movement is determined using another apparatus to which the apparatus for providing connection is directly and/or indirectly connected.

The apparatus for providing audio connection may be arranged to provide other types of connection function in addition to audio. For example, the apparatus may also be for providing video connection.

The apparatus for providing audio connection may be a connection head of an (e.g. audio/video) connector.

The apparatus for providing audio connection may be module for one or more of a (e.g. audio/video) connector, an A/V jack/plug, and a headset/earpiece/headphone.

The connection element may be arranged to be symmetrical around its longitudinal axis. The connection element may not be symmetrical around its longitudinal axis (axis of insertion). The connection element may be arranged to be a USB connection element.

The apparatus for providing audio connection may be for providing wireless connection over an air interface (e.g. using the short range Bluetooth™ protocol).

The speaker arrangement may comprise multiple speakers. The speaker arrangement may comprise a single speaker. The speaker arrangement may comprise one, two, three, four, five or more speakers. The speaker arrangement may comprise one or more loudspeakers and/or ear-speakers.

In a third aspect, there is provided a method of controlling an audio setting providable by a speaker arrangement, comprising detecting movement of an apparatus for providing audio connection, and based on said movement controlling the an audio setting providable by the speaker arrangement.

In a fourth aspect, there is provided a computer program for use with an apparatus for providing audio connection of a speaker arrangement, the computer program comprising computer code arranged to allow for detection of movement of the apparatus for providing audio connection, and based on said movement provide for controlling of an audio setting providable by the speaker arrangement.

The computer program may be stored on a memory which may be the memory of the apparatus for providing audio connection and/or the apparatus for providing audio to the speaker arrangement and/or some other apparatus to which the apparatus for providing audio connection is directly/indirectly connected. The computer program may be stored on a memory stick or storage medium which may not necessarily be part of an associated apparatus e.g. stored on a CD for transportation.

In a fifth aspect, there is provided a means for providing audio connection of means for audio output, with a means for providing audio to the means for audio output, using a means for connection of the means for providing audio connection, wherein the means for providing audio connection comprises a means for user input arranged to provide for control of an audio setting, providable by the means for audio output, based on detected movement of the means for providing audio connection.

In a sixth aspect, there is provided a connector for a speaker arrangement, to provide for connection of the speaker arrangement with an apparatus for providing audio to the speaker arrangement, wherein the connector comprises a user input interface arranged to provide for control of an audio setting, providable by the speaker arrangement, based on detected movement of the connector.

In a seventh aspect, there is provided a connector body of a speaker arrangement, adaptable to connect with an apparatus for providing audio to the speaker arrangement, using a connection element of the connector body, wherein the connector body comprises a user input interface arranged to control an audio setting of the audio, providable by the speaker arrangement, based on detected movement of the connector body.

The present invention includes one or more corresponding aspects, embodiments or features in isolation or in various combinations whether or not specifically stated (including claimed) in that combination or in isolation. Corresponding means for performing one or more of the discussed functions are also within the present disclosure.

The above summary is intended to be merely exemplary and non-limiting.

### BRIEF DESCRIPTION OF THE FIGURES

A description is now given, by way of example only, with reference to the accompanying drawings, in which:—

FIG. 1 shows an apparatus according to one embodiment of the present invention;

FIG. 2 shows the apparatus of FIG. 1 in use;

FIG. 3 shows a further embodiment of an apparatus;

FIG. 4a shows a further embodiment of an apparatus, and FIG. 4b shows this apparatus is use; and

FIG. 5 shows a further embodiment of an apparatus;

FIG. 6 shows a flow chart for the method of performing the operation achieved by an apparatus.

### DESCRIPTION OF SPECIFIC EMBODIMENTS

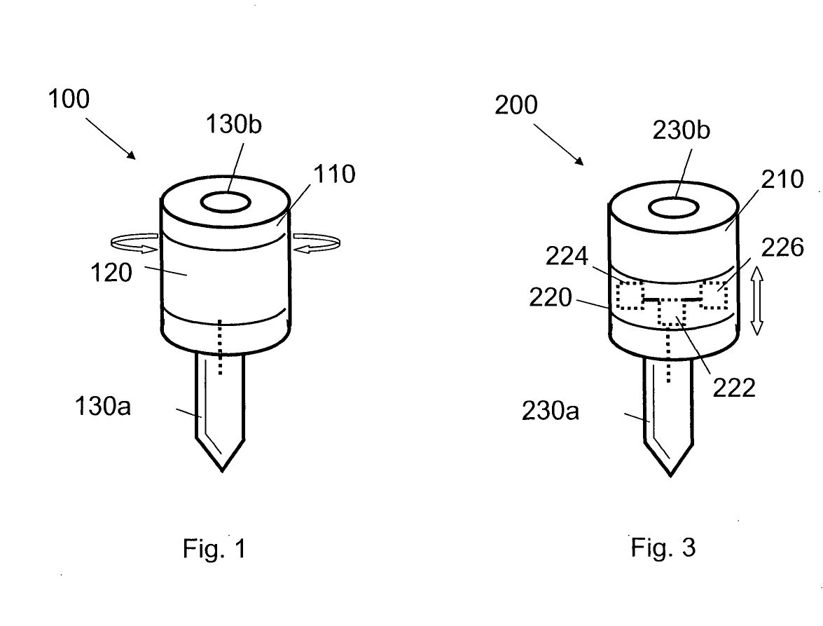

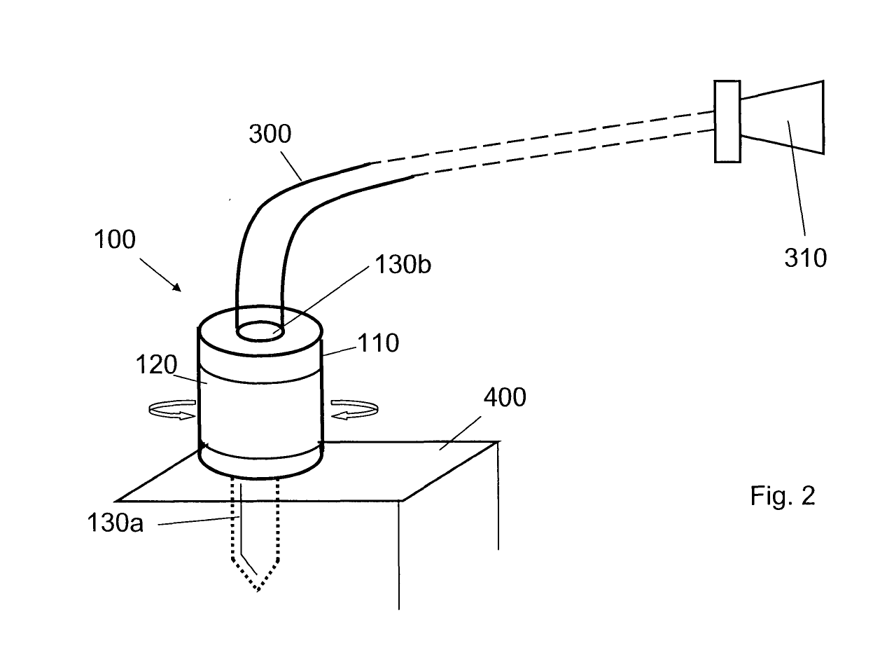

FIG. 1 shows an apparatus 100 for providing audio connection of a speaker arrangement (e.g. 310 of FIG. 2) with an apparatus for providing audio to the speaker arrangement (e.g. 400 of FIG. 2). In the present embodiment, this is provided as a connector 100. The connector 100 comprises a main body 110, a user input interface 120, and two connection elements 130a, 130b.

In the present embodiment, the first connection element 130a is provided as a male connection element and the second connection element 130b is provided as a female connection element (e.g. jack and jack-socket). The first connection element 130a is arranged to cooperate with a complementary female connection element of an apparatus for providing audio, such as an MP3 player, mobile telephone, PDA, laptop or the like. The second connection element 130b is arranged to cooperate with a complementary male connector element of a speaker arrangement, such as a headset, output speakers, earpiece, headphone, multimedia display, or the like.

In the present embodiment, the main body 110 of the connector 100 is substantially cylindrical. The user input interface 120 is arranged as a rotatable bezel, configured to be rotatably moveable around the main body 110. In the present embodiment the user input interface 120 is in communication with the first communication element 130a. The user input interface 120 is provided with a potentiometer, and is arranged such that rotation thereof provides an observable variable resistance to the first connection element 130a.

FIG. 2 shows the connector 100 of the present arrangement in use. In this arrangement the second connection element 130b is connected to a speaker arrangement 300, comprising an output speaker 310. The first connection element 130a is connected to an apparatus for providing audio, which in the present embodiment is an audio device 400, such as a mobile phone (not shown in detail).

The audio device 400 is arranged to output an audio signal to the speaker 300, via the connector 100. By rotating the user input interface 120, a user is able to alter the observable impedance of the user input interface 120, and thus reduce or increase the strength of the audio signal being transmitted to the speaker 300. In this regard, a user is able to control the volume of an audio signal being emitted by the speaker 310.

While in the present embodiment the user input interface 120 is arranged as a variable potentiometer, in alternative embodiments the connector 100 may output a control signal to the audio device 400. FIG. 3 shows such an arrangement.

In this embodiment, a connector 200 comprises a main body 210, a user input interface 220 and two connection elements 230a, 230b in a similar manner to that described above.

The user input interface 220 is arranged as a slidable bezel, configured to be slidably operable on the main body 210 of the connector 200 (e.g. translatable in an axial direction, such as a longitudinally axial direction, on the main body 210). In the present embodiment, the user interface element 220 is additionally provided with control circuitry 222, a slide sensor 224, and a haptic sensor 226. The slide sensor 224 and the haptic sensor 226 are both in communication with the control circuitry 222. In the present embodiment, the control circuitry 222 of the user input interface 220 is communication with the first communication element 230a.

The slide sensor 224 is arranged to communicate to the control circuitry 222 a slide output signal indicative of the translation of the user input interface 220 on the main body, such as the translation from a fixed, or starting, position, or the like. The haptic sensor 226 is arranged to communicate to the control circuitry 222 a haptic output signal indicative of the presence or absence of a user's touch on the user input interface 230. In the present embodiment, this is achieved by observing the conductive properties of a user's touch, as will be readily understood by the skilled reader.

The control circuitry 222 is arranged to communicate to the first communication element 230a a control signal indicative of the translation of the user input interface when it is perceived that a user is actuating the user input interface 220 (e.g. by observation of haptic sensor).

In use, and when connected to an audio device 400 and speaker arrangement 300 as described above, an audio device 400 is a able to observe a control signal from the first connection element 230a and, by using the control signal, alter the strength of the audio signal being transmitted to a speaker arrangement 300, connected via the connector 200.

It will readily be appreciated that while in the above embodiment the user input interface was slidable upon the main body 210, in alternative embodiments the user input interface 220 may comprise the main body 210. In such an arrangement, the user input interface/main body 220, 210 may be slidable on one, or both, of the connection elements 230a, 230b. In alternative embodiments, movement of the connection element 230a, 230b (e.g. the male connection element 230a), may provide the user input interface 220. A skilled party would readily be able to implement such an arrangement.

Similarly while in the above arrangement the user input interface 220 is provided with control circuitry, it will readily be appreciated that this need not be the case, and that in alternative embodiments the connector 200 may be arranged to provide both or one of the haptic output signal and the slide output signal to the connection element 230a, 230b. In such an arrangement, a further part of either device, such as an audio device 400, or the speaker arrangement, such as the speakers 310, may be arranged to generate the control signal accordingly.

In further arrangements still, the control signal of the connector may be used to vary a potentiometer, or the like, within the connector in a similar manner to that described in relation to FIG. 1. In such an arrangement, the control signal need not be communicated to either the audio device 400, or the speaker arrangement 300. A person skilled in the art would readily be able to implement such an arrangement.

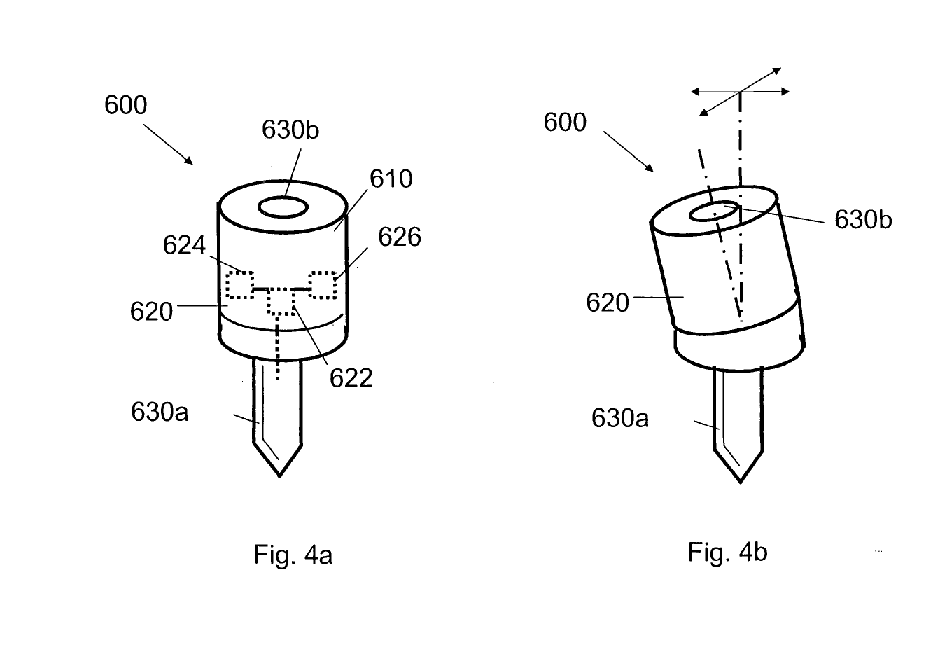

FIG. 4a shows a further embodiment of a connector 600. In this embodiment the connector 600 is provided with a main body 610, a user input interface 620 and two connection elements 630a, 630b, each connection element 630a, 630b being arranged to connect to further apparatus 300, 400 in a similar manner as described above.

In the present embodiment, the user input interface 620 is provided as a deflecting region on the main body 610. The user input interface 620 is arranged to deflect a portion of the main body 610 from a central axis by a particular angle, which in the present embodiment is variable (e.g. analogue rather than discrete, although discrete deflection may alternatively be used).

The user input interface 620 is arranged to deflect in four directions: side to side and back to front. The user input interface 620 is additionally provided with a control circuitry 662, a deflection sensor 624, and a haptic sensor 626.

The deflection sensor 624 is arranged to communicate to the control circuitry 622 a defection output signal indicative of the angle of deflection and direction of defection of the user input interface 620 on the main body, such as the deflection from a fixed, or starting, position, or the like (e.g. deflection from the central axis).

The haptic sensor 626 is arranged communicate to the control circuitry 622 a haptic output signal indicative of the presence or absence of a user's touch on the user input interface 630. In the present embodiment, this is achieved by observing the conductive properties of a user's touch, as will be readily understood by the skilled reader.

The control circuitry 622 is arranged to communicate to the first communication element 630a a control signal indicative of the deflection of the user input interface 620 when it is perceived that a user is actuating the user input interface 620 (e.g. by observation of haptic sensor 626).

In use, and when connected to an audio device 400 and speaker arrangement 300 as described above, an audio device 400 is a able to observe an control signal communicated from the first connection element 630a of the connector 600 when the user input interface 620 is deflected (as shown in FIG. 4b). In such an arrangement, the control signal may be used to alter the strength of an audio signal being transmitted to a speaker arrangement 300, connected via the connector 600.

In such an arrangement, such alteration of signal strength might not occur if a user was not touching the user input interface 620 (e.g. reducing the likelihood of audio alteration during accidental movement of the user input interface 620).

The skilled person will readily appreciate that in addition to the variation in audio signal, the control signal may be used to control further features/properties of the audio, audio device/speaker arrangement 300, 400, such as tone/pitch, etc. or other audio processing characteristics (e.g. equalisation, or the like). This may be achieved as the user input interface 620 in the present embodiment has further degrees of freedom and/or with the use of one selection of the property using a menu driven user interface (e.g. on the PDA). In further arrangements, the user input interface 620 may be arranged to be deformable in more than four directions, such as 6, 8, 10, 12, etc. It may be deformable in a full 360 degree.

Similarly, while a deflection sensor 624 and control circuit 622 are used, in alterative embodiments the deflection may be measured by variation in resistance of a potentiometer, or the like, in a similar manner to the embodiment shown in FIG. 1.

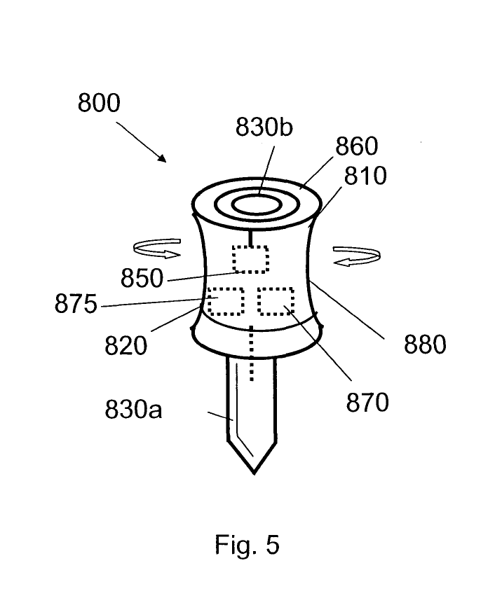

FIG. 5 shows a further embodiment of a connector 800. The connector 800 in this arrangement is similar to that provided in FIG. 1. The connector 800 is provided with a main body 810, a user input interface 820, and two connection elements 830a, 830b. Again the first connection element 830a is provided as a male connector and the second connection element 830b is provided as a female connection element.

In this embodiment, the main body 810 of the connector 800 is formed as a cylindrical shape of varying cross section so as to provide a holding part 880 in the middle region of the main body 810. The holding area 880 having a cross-section reduced in size to that of the main body 810.

The connector 800 of the present embodiment is further provided with processing circuitry 870 and a power supply 875, such as a battery, associated therewith. The processing circuitry 870 is in communication with the first connection element 830a and the second communication element 830b and is arranged to condition (e.g. signal process) a signal being transmitted between the first connection element 830a and the second communication element 830b. The user input interface 820 is again arranged as a rotatable bezel, configured to be rotatably moveable around the body 810. The rotatable bezel is in communication with processing circuitry 870.

In this arrangement, the connector 800 is further provided with an actuation sensor 850 and an actuation output 860, which in the present embodiment is an LED array provided on an upper region of the connector 800. The actuation sensor 850 is in communication with the user input interface 820 and with the actuation output 860, and is arranged to provide an actuation signal to the actuation output 860 when the user input interface 820 is activated. The actuation output 860 is arranged to activate (e.g. illuminate, flash, etc.) upon receipt of the actuation signal.

In use, a user may connect the connector 800 to a device 400 and speaker arrangement 300 in a similar manner to that as described above. In this embodiment however, a user may use the holding area 880 to facilitate easy insertion/removal/actuation. Upon movement of the user input interface 820 (e.g. rotation to alter volume, etc.) the actuation output 860 is activated by the actuation sensor 850. In such an arrangement, a user is able to identify when an input via the user input interface 820 is being made.

It will readily be appreciated that in alternative embodiments the actuation output may be provided by an alternative output, such as an audio output, pressure output (vibration), or combination of audio/visual/pressure output. The output may be provided at a speaker arrangement 300, or the like, to which the connector 800 is connected (e.g. an audio output through a speaker 300).

In addition, as an input is received from the user input interface 820 a signal, such as an audio signal, being transmitted through the connector 800 is modified by the processing circuitry. In the present embodiment, rotational actuation of the user input interface causes the amplitude of the audio signal to be modified (i.e. increase/decrease in volume). In such an arrangement, the audio signal, or the like, may be processed (e.g. alter tone/volume, etc), by the connector 800, without the knowledge of a device 400 to which the connector 600 is connected. Although in this embodiment a power supply 875 is provided by the connector 800, in alternative embodiments this may be provided by a further apparatus (e.g. the audio device) to which the connector is attached (e.g. when the connector is connecter by a USB interface, or the like).

Although not shown, similar power supply arrangements may exist for all provided embodiments. In some embodiments, actuation of the user input interface 120, 220, 620, 820 may provide power for the connector 100, 200, 600, 800 (e.g. piezoelectric, micro-dyno, etc).

It will readily be appreciated that any feature(s) of any of the above embodiments may be used in combination with any of the other features of any other embodiments. For example the user input interface 120, 220 may be rotatable and slidable on the main body of the connector 100, 200, and may comprising processing circuitry 870, or the like. A person skilled in the art will readily be able to implement such an arrangement. Similarly a skilled reader will readily appreciate that the main body 110, 210, 610, 810 (and/or the associated connection elements) need not be cylindrical (or substantially cylindrical, and/or substantially symmetrical) and may be any shape, such a cubic, conic, etc.

In addition it will readily be appreciated that the connector 100, 200, 600, 800 may comprise the speaker arrangement 300, or a portion thereof, such as a cable connection, or the like. Additionally, it will be appreciated that while in the above embodiments the connector 100, 200, 600, 800 is provided with a first connection element 130a, 230a, 630a, 830a, which is male, and a second connection element 130b, 230b, 630b, 830b which is female, this need not be the case. The connector 100, 200, 600, 800 may be provided with alternative connections elements, or connection elements that are all female, or all male. The connector may be provided with any number of connection elements 130, 230, 630, 830 for connecting to a plurality of further apparatuses. A skilled person will readily appreciate that the above exemplar embodiments are not limited in this regard.

In further embodiments still, the user input interface 120, 220, 620, 820 of the connector 100, 200, 600, 800 may be actuated by any number of other apparatus, such as by motion sensors, or the like, e.g. by using an accelerometer, gyro-MEM. This may be in addition or alternative to the embodiments described.

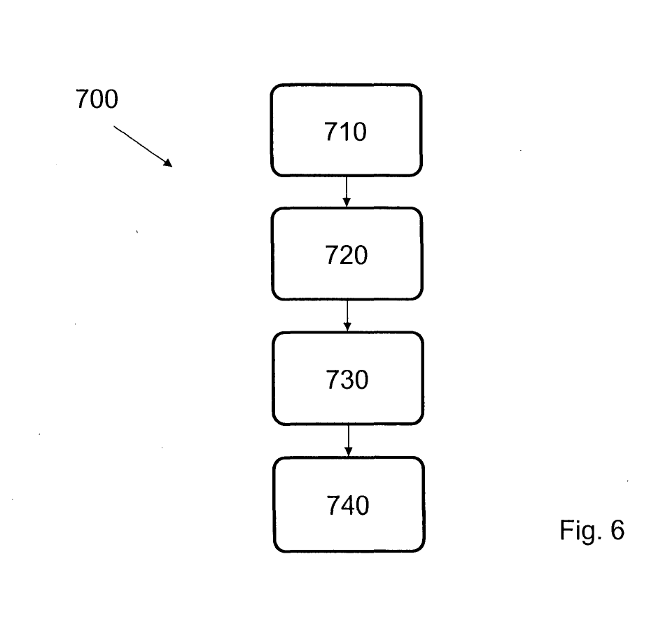

FIG. 6 shows a flow chart 700 showing use of a connector 100, 200, 600, 800 according to the above embodiments. In a first step 710, a user connects the connector 100, 200, 600, 800 to a device 400, such as an audio device. In a second step 720, a user connects the connector 100, 200, 600, 800 to a speaker arrangement 300, such as a pair of headphones. In a third step 730, the user initiates playing music from the device 400 through the connector 100, 200, 600, 800 to the speaker arrangement. In a fourth step 740, the user actuates the user input interface 120, 220, 620, 820 to alter a property of the signal reaching the speaker arrangement, such as the volume, etc.

It will readily be appreciate to the skilled user, that while the above embodiment detail wired communication, alternative arrangements may provide for wireless communication. In such arrangement, the connector 100, 200, 600, 800 may be connected to a device 400, while a speaker arrangement may be connected wirelessly to the connector 100, 200, 600, 800 or device 400.

Similarly, while in the above embodiments the device 400 is shown as an audio device, it may be that the device 400 is a video device, or a multimedia device, such as a personal video device.

In such an arrangement, the speaker arrangement 300 may be provided with a visual output, such as a display or the like. The user input interface 120, 220, 620, 820 may be arranged to alter the properties of the output on the display, such as contrast, colour, etc. This may be in addition, or alternative, to altering audio properties. A skilled person would readily understand and be able it implement such further arrangements.

Although is certain embodiments, a wire may be permanently connected to a connection element (130b, FIG. 2) to provide for permanent connection of the speaker arrangement (300/310) to the connector 100, in other embodiments, the speaker arrangement (300/310) may be repeatably connectable to the connector (100) via the connection element (130b).

It will be appreciated to the skilled reader that the one or more of the apparatus may be arranged such that they become configured to carry out the desired operations only when enabled, e.g. switched on, in a connected state or the like. In such cases, they may not necessarily have the appropriate software loaded into the active memory in the non-enabled (e.g. switched off state) and only load the appropriate software in the enabled (e.g. on state). The apparatus may comprise hardware circuitry and/or firmware. The apparatus may comprise software loaded onto memory.

It will be appreciated that the aforementioned circuitry/apparatus/elements may have other functions in addition to the mentioned functions, and that these functions may be performed by the same circuit/apparatus/element.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features. In view of the foregoing description it will be evident to a person skilled in the art that various modifications may be made within the scope of the invention.

While there have been shown and described and pointed out fundamental novel features of the invention as applied to preferred embodiments thereof, it will be understood that various omissions and substitutions and changes in the form and details of the devices and methods described may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto. Furthermore, in the claims means-plus-function clauses are intended to cover the structures described herein as performing the recited function and not only structural equivalents, but also equivalent structures. Thus although a nail and a screw may not be structural equivalents in that a nail employs a cylindrical surface to secure wooden parts together, whereas a screw employs a helical surface, in the environment of fastening wooden parts, a nail and a screw may be equivalent structures.

1.-26. (canceled)

27. An apparatus for providing audio connection of a speaker arrangement, with an apparatus for providing audio to the speaker arrangement, using a male connection element of the apparatus for providing audio connection, wherein the apparatus for providing audio connection comprises a male connection element or connector body associated with a male connection element, and a user input interface configured to provide for control of an audio setting of the audio, providable by the speaker arrangement, based on detected movement of the male connection element/associated connector body.

28. An apparatus for providing audio connection according to claim 27, wherein the user input interface is configured to provide for control of one or more of a volume of audio and quality of audio setting.

29. An apparatus for providing audio connection according to claim 27, wherein the apparatus for providing audio connection is an audio accessory for a portable electronic device.

30. An apparatus for providing audio connection according to claim 27, wherein the apparatus for providing audio connection is one or more of a connector, headset, earpiece, headphone, speaker, A/V plug, or a module for the same, and the apparatus for providing audio to the speaker arrangement is a portable electronic device for providing one or more of audio/text/video communication functions, interactive/non-interactive viewing functions, music recording/playing functions, downloading/sending of data functions, image capture function, and gaming functions.

31. An apparatus for providing audio connection according to claim 27, wherein the apparatus is configured to provide for the control of an audio setting, when the apparatus for providing audio connection is in a connected state, by detecting movement of one or more of the male connection element, the apparatus for providing audio connection, and the connector.

32. An apparatus for providing audio connection according to claim 27, wherein the apparatus is configured to provide for control of an audio setting by detecting one or more of rotational/translational movement about/along a longitudinal axis of the apparatus for providing audio connection.

33. An apparatus for providing audio connection according to claim 27, wherein the apparatus is configured to control an audio setting by detecting deflection of the apparatus for providing audio connection with respect to a non-deflected configuration of the apparatus for providing audio connection.

34. An apparatus for providing audio connection according to claim 27, wherein the apparatus for providing audio connection comprises one or more holding areas to allow the apparatus for providing audio connection to be held by a user, and wherein the apparatus is configured to control an audio setting by detecting movement of the holding area(s).

35. An apparatus for providing audio connection according to claim 27, wherein the apparatus for providing audio connection is configured to comprise a plurality of connection elements, one to allow connection to a speaker arrangement and another to allow connection to an apparatus for providing audio.

36. An apparatus for providing audio connection according to claim 27, wherein the user input interface is configured to also provide user output to provide a visual indication that movement has been detected.

37. An apparatus for providing audio connection according to claim 27, wherein the apparatus for providing audio connection is configured to provide other types of connection function in addition to audio.

38. An apparatus for providing audio connection according to claim 27, wherein the apparatus for providing audio connection is a connection head of a connector.

39. An apparatus for providing audio connection according to claim 27, wherein the apparatus for providing audio connection is configured for providing wireless connection over an air interface.

40. A method of controlling an audio setting providable by a speaker arrangement, comprising detecting movement of an apparatus for providing audio connection, and based on said movement controlling an audio setting providable by the speaker arrangement, wherein the apparatus for providing audio connection comprises a male connection element or connector body associated with a male connection element and the detected movement is of the male connection element/associated connector body.

41. A computer program for use with an apparatus for providing audio connection of a speaker arrangement, the computer program comprising computer code configured to:
allow for detection of movement of the apparatus for providing audio connection, and
provide for controlling of an audio setting providable by the speaker arrangement based on said movement, wherein the apparatus for providing audio connection comprises a male connection element or connector body associated with a male connection element and the detected movement is of the connection element/associated connector body.

42. An accessory, the accessory for providing audio connection of a speaker arrangement to an apparatus for providing audio to the speaker arrangement, the accessory comprising:
a male connection element or a connector body; and
an associated user input interface;
wherein the user input interface is associated with the male connection element/connector body to detect movement of the male connection element/connector body, and based on the detected movement provide for control of an audio setting of the audio, providable by the speaker arrangement.

43. An accessory according to claim 42, wherein the connector body is associated with a male or female connection element.

44. An accessory according to claim 42, wherein the accessory is one or more of a connector, headset, earpiece, headphone, speaker, A/V plug, or a module for the same.

45. An accessory according to claim 42, wherein the apparatus for providing audio to the speaker arrangement is a portable electronic device for providing one or more of audio/text/video communication functions, interactive/non-interactive viewing functions, music recording/playing functions, downloading/sending of data functions, image capture function, and gaming functions.

46. An accessory according to claim 42, wherein the detected movement is one or more of rotational/translational/deflected movement about/along a longitudinal axis of the accessory.
